(19) United States
(12) Patent Application Publication
(10) Pub. No.: US 2026/0075700 A1
(43) Pub. Date: Mar. 12, 2026

(54) ELECTRONIC ASSEMBLY

(71) Applicants: INVENTEC (PUDONG) TECHNOLOGY CORPORATION, Shanghai (CN); INVENTEC CORPORATION, Taipei City (TW)

(72) Inventor: Jih Lung LIN, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/195,382

(22) Filed: Apr. 30, 2025

(30) Foreign Application Priority Data
Sep. 6, 2024 (CN) 202411252321.0

(51) Int. Cl. H05K 1/02; H05K 1/14; H05K 7/20

(52) U.S. Cl. CPC H05K 1/0203; H05K 1/144; H05K 7/20145; H05K 7/20154; H05K 7/20409; H05K 7/20509; H05K 2201/066

(57) ABSTRACT

An electronic assembly including a first circuit board assembly, a second circuit board assembly, a heat sink and a thermally conductive frame. The first circuit board assembly includes a first circuit board and a first heat source. The second circuit board assembly includes a second circuit board and a second heat source. The heat sink is located between the first circuit board and the second circuit board and includes a base and a plurality of heat dissipation fins. The plurality of heat dissipation fins protrude from a side of the base. The base is thermally coupled to the second heat source. The thermally conductive frame protrudes from the side of the base. Two opposite sides of the thermally conductive frame are thermally coupled to the base and the first heat source, respectively, and the thermally conductive frame forms at least one heat dissipation channel.

### CROSS-REFERENCE TO RELATED APPLICATIONS

This non-provisional application claims priority under 35 U.S. C. § 119(a) on Patent Application No(s). 202411252321.0 filed in China, on September 6th, 2024, the entire contents of which are hereby incorporated by reference.

### BACKGROUND OF THE INVENTION

### Technical Field of the Invention

The invention relates to an electronic assembly, more particularly to an electronic assembly including heat source and heat sink.

### Description of the Related Art

In general, in order to enhance the space utilization, it is common for the electronic component to include an electronic assembly configured by two adjacent circuit board assemblies. In such electronic assembly, to effectively cool the two circuit board assemblies, each circuit board assembly is required to be cooled by an exclusive heat sink.

However, the heat sink has a complex structure and thus is required to be manufactured by a complex mold. In this way, cooling each circuit board assembly by exclusive heat sink (manufactured by exclusive mold) significantly increases the manufacture cost of the electronic assembly. That is, conventional electronic assembly is unable to effective cool the circuit board assemblies without significantly increasing the manufacture cost thereof.

### SUMMARY OF THE INVENTION

The invention provides an electronic assembly allowing the circuit board assemblies to be effective cooled without significantly increasing the manufacture cost thereof.

One embodiment of this invention provides an electronic assembly including a first circuit board assembly, a second circuit board assembly, a heat sink and a thermally conductive frame. The first circuit board assembly includes a first circuit board and a first heat source disposed on the first circuit board. The second circuit board assembly includes a second circuit board and a second heat source disposed on the second circuit board. The first circuit board and the second circuit board are spaced apart from each other. The heat sink is located between the first circuit board and the second circuit board and includes a base and a plurality of heat dissipation fins. The plurality of heat dissipation fins protrude from a side of the base. The base is thermally coupled to the second heat source. The thermally conductive frame protrudes from the side of the base. Two opposite sides of the thermally conductive frame are thermally coupled to the base and the first heat source, respectively, and the thermally conductive frame forms at least one heat dissipation channel.

According to the electronic assembly disclosed by above embodiments, the base of the heat sink is thermally coupled to the second heat source, two opposite sides of the thermally conductive frame respectively are thermally coupled to the base of the heat sink and the first heat source, and the thermally conductive frame forms the at least one heat dissipation channel. With the aforementioned configuration of the thermally conductive frame, the thermally conductive frame not only acts as the medium to transfer heat between the first heat source and the heat sink, but also allows the cold air to flow through the heat dissipation channel without being blocked. Thus, the heat generated by the first heat source and the second heat source is effectively absorbed by a single one heat sink and the thermally conductive frame cooperating with each other, thereby saving the cost for manufacturing multiple heat sinks having complex structures. Accordingly, the first circuit board assembly and the second circuit board assembly are effective cooled without significantly increasing the manufacture cost of the electronic assembly.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a perspective view of an electronic assembly according to a first embodiment of the invention;

FIG. 2 is a side cross-sectional view of the electronic assembly in FIG. 1 taken along line 2-2;

FIG. 3 is a partially enlarged exploded view of a heat sink, a thermally conductive frame and a screw of the electronic assembly in FIG. 1;

FIG. 4 is a partially enlarged side cross-sectional view of the electronic assembly in FIG. 2;

FIG. 5 is a perspective view of an electronic assembly according to a second embodiment of the invention;

FIG. 6 is a partially enlarged side cross-sectional view of the electronic assembly in FIG. 5 taken along line 6-6; and

FIG. 7 is a partially enlarged exploded view of a heat sink, a thermally conductive frame and a screw of the electronic assembly in FIG. 5.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

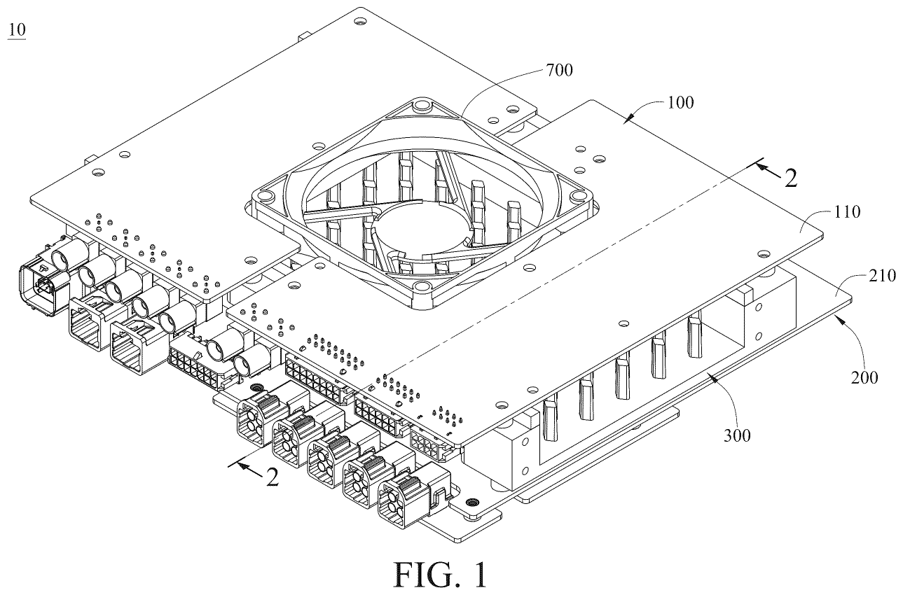

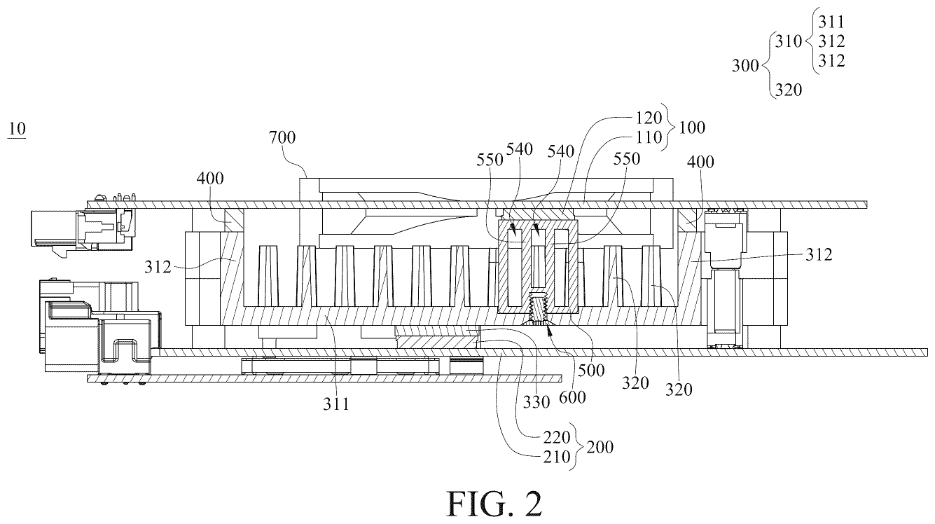

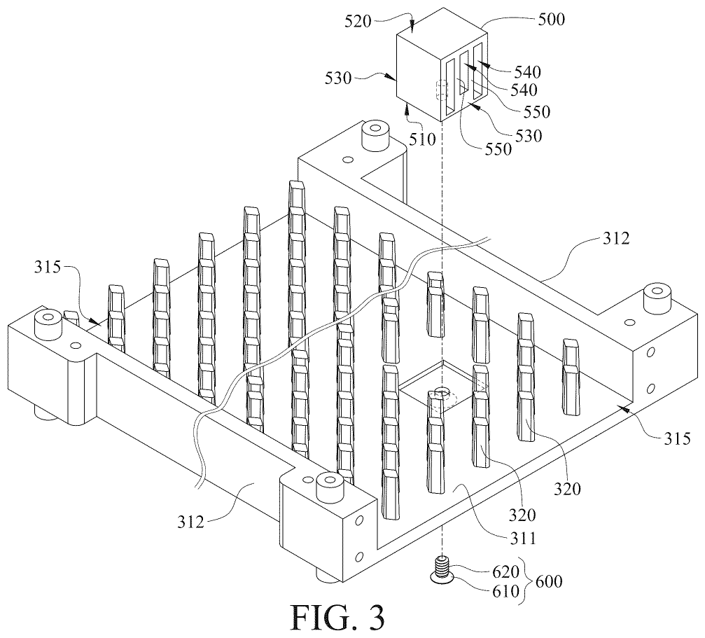

Please refer to FIGS. 1 to 3. FIG. 1 is a perspective view of an electronic assembly 10 according to a first embodiment of the invention. FIG. 2 is a side cross-sectional view of the electronic assembly 10 in FIG. 1 taken along line 2-2. FIG. 3 is a partially enlarged exploded view of a heat sink 300, a thermally conductive frame 500 and a screw 600 of the electronic assembly 10 in FIG. 1.

In this embodiment, the electronic assembly 10 includes, for example, a first circuit board assembly 100, a second circuit board assembly 200, the heat sink 300, two sealing pads 400, the thermally conductive frame 500, the screw 600 and a fan 700.

In this embodiment, the first circuit board assembly 100 includes a first circuit board 110 and a first heat source 120 disposed thereon. The second circuit board assembly 200 includes a second circuit board 210 and a second heat source 220 disposed thereon. The first circuit board 110 and the second circuit board 210 are spaced apart from each other.

In this embodiment, the heat sink 300 is located between the first circuit board 110 and the second circuit board 210, and includes a base 310 and a plurality of heat dissipation fins 320. In addition, the heat sink 300 is made by, for example, die casting. The base 310 includes a bottom plate 311 and two side plates 312. The two side plates 312 are respectively connected to two opposite sides of the bottom plate 311 so that the two side plates 312 and the bottom plate 311 together form two openings 315. The heat dissipation fins 320 protrude from a side of the bottom plate 311. A side of the bottom plate 311 located away from the heat dissipation fins 320 is thermally coupled to the second heat source 220 by, for example, a thermally conductive protrusion 330 and a thermally conductive pad (not shown).

As shown in FIG. 2, the two sealing pads 400 are respectively clamped between the two side plates 312 and the first circuit board 110 to enhance the air tightness between the heat sink 300 and the first circuit board 110. The two sealing pads 400 are, for example, foams. Note that in other embodiments, if the first heat source and the second heat source have low power, the electronic assembly may not include the sealing pads 400.

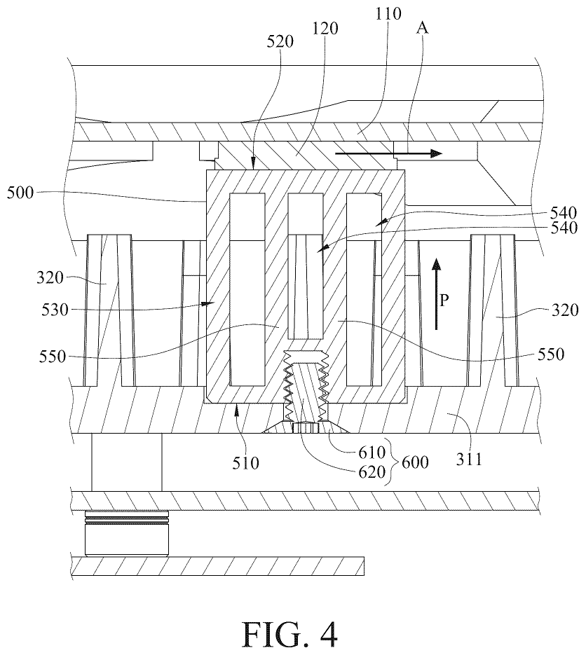

Please refer to FIGS. 3 and 4. FIG. 4 is a partially enlarged side cross-sectional view of the electronic assembly 10 in FIG. 2. In this embodiment, the thermally conductive frame 500 and the heat dissipation fins 320 protrude from the same side of the bottom plate 311. The thermally conductive frame 500 is made by, for example, aluminum extrusion, and has a first coupling surface 510, a second coupling surface 520 and two ventilation surfaces 530. The first coupling surface 510 and the second coupling surface 520 face away from each other. The two ventilation surfaces 530 face away from each other and connect the first coupling surface 510 and the second coupling surface 520. In addition, the two ventilation surfaces 530 face toward the two openings 315, respectively. The first coupling surface 510 and the second coupling surface 520 are thermally coupled to the bottom plate 311 and the first heat source 120, respectively. The second coupling surface 520 is thermally coupled to the first heat source 120 by, for example, a thermally conductive pad (not shown).

Moreover, in this embodiment, the thermally conductive frame 500 forms, for example, a plurality of heat dissipation channels 540 penetrating through the two ventilation surfaces 530. Specifically, in this embodiment, the thermally conductive frame 500 further has a plurality of partitions 550. The partitions 550 define the heat dissipation channels 540 that are not in direct fluid communication with each other. In other embodiments, there may be one heat dissipation channel. That is, in other embodiments, the thermally conductive frame may not have the partitions.

Moreover, in this embodiment, an arranging direction A of the heat dissipation channels 540 is, for example, perpendicular to a protruding direction P along which the heat dissipation fins 320 protrude from the bottom plate 311. Thus, a cold air is facilitated to flow to the heat dissipation fins 320 through the heat dissipation channels 540. In other words, the cold air flowing to the heat dissipation fins 320 through the heat dissipation channels 540 is subjected to a small resistance. However, in other embodiments, if the first heat source and the second heat source have low power, the arranging direction of the heat dissipation channels may be parallel to the protruding direction along which the heat dissipation fins protrude from the bottom plate.

In this embodiment, the thermally conductive frame 500 is fixed to the base 310 via, for example, the screw 600. In detail, the screw 600 includes a head part 610 and a body part 620 connected to each other. The body part 620 is screwed into the thermally conductive frame 500 and the bottom plate 311, and the head part 610 rests on a side of the bottom plate 311 located away from the heat dissipation fins 320. The head part 610 is, for example, flush with the bottom plate 311.

Please refer to FIGS. 1 and 2 again. The fan 700 and the first circuit board assembly 100 are located on the same side of the heat sink 300. The fan 700 is fixed to, for example, the base 310 of the heat sink 300, and is configured to blow an airflow (not shown) flowing to the heat dissipation fins 320 through the heat dissipation channel 540. In other embodiments, the electronic assembly may not include the fan 700, and the airflow may be blown by a fan external to the electronic assembly.

With the aforementioned configuration of the thermally conductive frame 500, the thermally conductive frame 500 not only acts as the medium to transfer heat between the first heat source 120 and the heat sink 300, but also allows the cold air (i.e., the airflow blown by the fan 700 or external fan) to flow through the heat dissipation channel 540 without being blocked. Thus, the heat generated by the first heat source 120 and the second heat source 220 is effectively absorbed by a single one heat sink 300 and the thermally conductive frame 500 cooperating with each other, thereby saving the cost for manufacturing multiple heat sinks 300 having complex structures. Accordingly, the first circuit board assembly 100 and the second circuit board assembly 200 are effective cooled without significantly increasing the manufacture cost of the electronic assembly 10.

Other embodiments are described below for illustrative purposes. It is to be noted that the following embodiments use the reference numerals and a part of the contents of the above embodiments, the same reference numerals are used to denote the same or similar elements, and the description of the same technical contents is omitted. For the description of the omitted part, reference may be made to the above embodiments, and details are not described in the following embodiments.

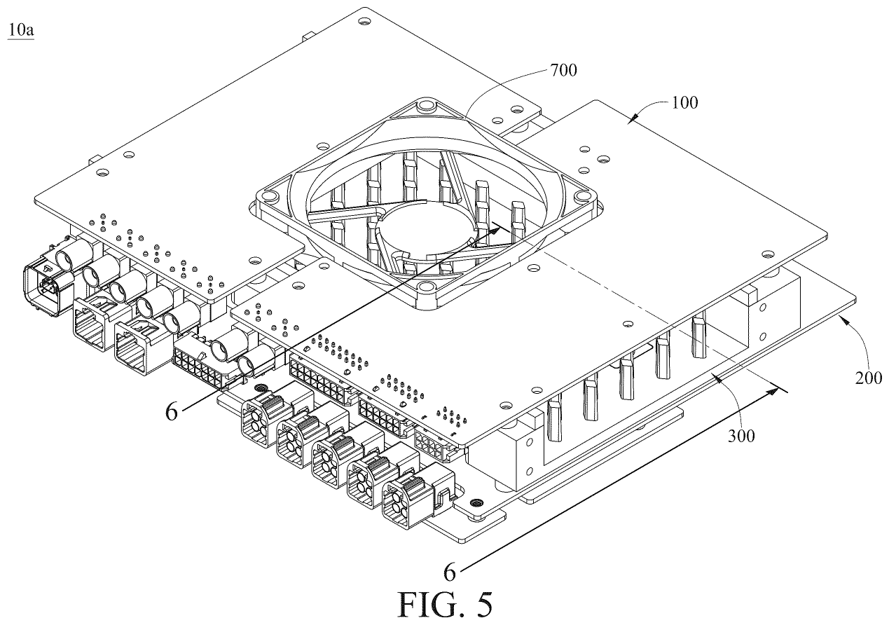

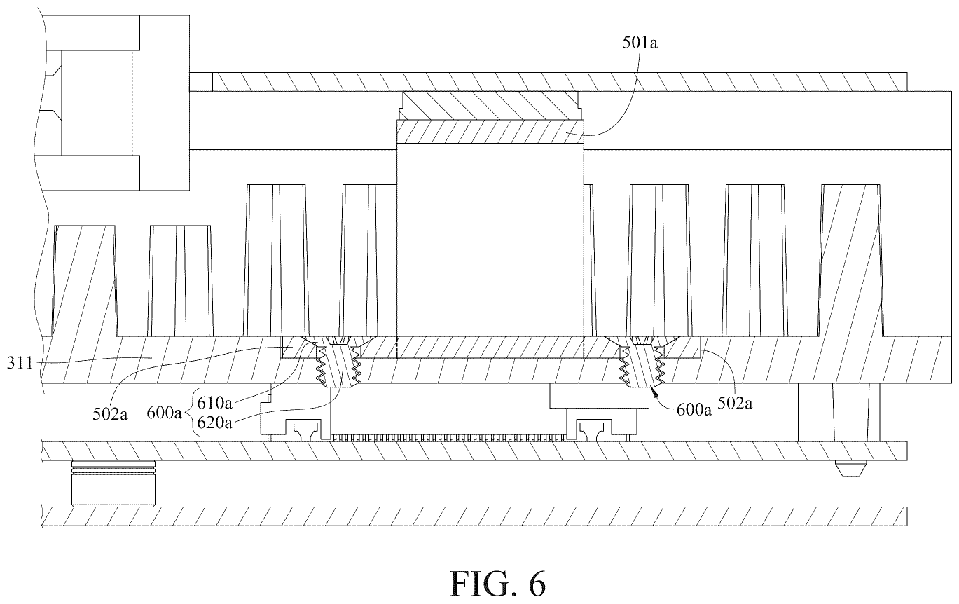

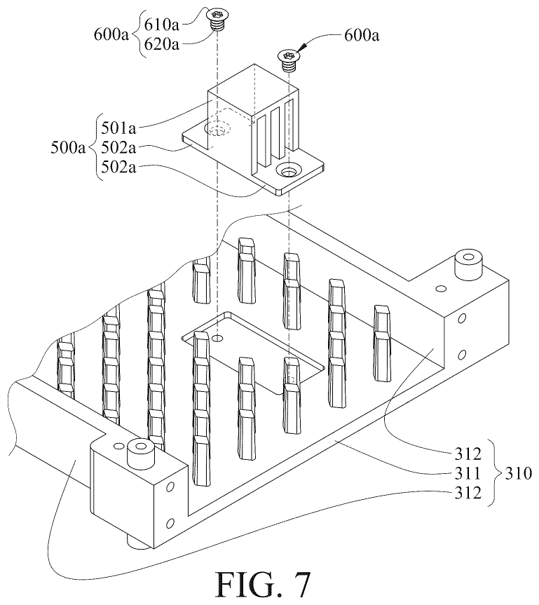

The invention is not limited by the manner for the thermally conductive frame to be fixed to the base. Please refer to FIGS. 5 to 7. FIG. 5 is a perspective view of an electronic assembly 10a according to a second embodiment of the invention. FIG. 6 is a partially enlarged side cross-sectional view of the electronic assembly 10a in FIG. 5 taken along line 6-6. FIG. 7 is a partially enlarged exploded view of the heat sink 300, a thermally conductive frame 500a and a screw 600a of the electronic assembly 10a in FIG. 5.

The only difference between the electronic assembly 10a of this embodiment and the electronic assembly 10 of the first embodiment is the manner for the thermally conductive frame 500a to be fixed to the base 310, and thus the descriptions of other similar parts are omitted. In this embodiment, the electronic assembly 10a includes two screws 600a. The two screws 600a each include a head part 610a and a body part 620a that are connected. The thermally conductive frame 500a includes a body part 501a and two mounting protrusions 502a. The two mounting protrusions 502a protrude from two opposite sides of the body part 501a, respectively. The two body parts 620a of the two screws 600a are screwed into the bottom plate 311, and are respectively screwed into the two mounting protrusions 502a. Also, the two head parts 610a of the two screws 600a rest on sides of the two mounting protrusions 502a located away from the bottom plate 311, respectively. The two head parts 610a are, for example, flush with the two mounting protrusions 502a, respectively.

Note that in other embodiments, the electronic assembly may not include the screw, and the thermally conductive frame may be fixed to the base by welding or soldering.

According to the electronic assembly disclosed by above embodiments, the base of the heat sink is thermally coupled to the second heat source, two opposite sides of the thermally conductive frame respectively are thermally coupled to the base of the heat sink and the first heat source, and the thermally conductive frame forms the at least one heat dissipation channel. With the aforementioned configuration of the thermally conductive frame, the thermally conductive frame not only acts as the medium to transfer heat between the first heat source and the heat sink, but also allows the cold air to flow through the heat dissipation channel without being blocked. Thus, the heat generated by the first heat source and the second heat source is effectively absorbed by a single one heat sink and the thermally conductive frame cooperating with each other, thereby saving the cost for manufacturing multiple heat sinks having complex structures. Accordingly, the first circuit board assembly and the second circuit board assembly are effective cooled without significantly increasing the manufacture cost of the electronic assembly.

In an embodiment of the invention, the electronic assembly of this invention may be applied in a server. The server may apply Artificial Intelligence (AI) computing, Edge Computing, or may be used as a 5G server, a cloud server or a Vehicle-to-everything (V2X) server.

In an embodiment of the invention, the electronic assembly of this invention may be applied in an automotive device, such as a carputer or a server of an In-Vehicle Infotainment (IVI), or may be applied in a 5G server, a cloud server or a Vehicle-to-everything (V2X) server.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. An electronic assembly, comprising:
a first circuit board assembly, comprising a first circuit board and a first heat source disposed on the first circuit board;
a second circuit board assembly, comprising a second circuit board and a second heat source disposed on the second circuit board, wherein the first circuit board and the second circuit board are spaced apart from each other;
a heat sink, located between the first circuit board and the second circuit board and comprising a base and a plurality of heat dissipation fins, wherein the plurality of heat dissipation fins protrude from a side of the base, and the base is thermally coupled to the second heat source; and
a thermally conductive frame, protruding from the side of the base, wherein two opposite sides of the thermally conductive frame are thermally coupled to the base and the first heat source, respectively, and the thermally conductive frame forms at least one heat dissipation channel.

2. The electronic assembly according to claim 1, wherein the thermally conductive frame has a first coupling surface, a second coupling surface and two ventilation surfaces, the first coupling surface and the second coupling surface face away from each other, the two ventilation surfaces face away from each other and connect the first coupling surface and the second coupling surface, the at least one heat dissipation channel penetrates through the two ventilation surfaces, and the first coupling surface and the second coupling surface are thermally coupled to the base and the first heat source, respectively.

3. The electronic assembly according to claim 2, wherein the thermally conductive frame has at least one partition, the at least one heat dissipation channel comprises a plurality of heat dissipation channels, and the at least one partition define the plurality of heat dissipation channels that are not in direct fluid communication with each other.

4. The electronic assembly according to claim 3, wherein an arranging direction of the plurality of heat dissipation channels is perpendicular to a protruding direction along which the plurality of heat dissipation fins protrude from the base.

5. The electronic assembly according to claim 2, wherein the base comprises a bottom plate and two side plates, the two side plates are respectively connected to two opposite sides of the bottom plate so that the two side plates and the bottom plate together form two openings, the plurality of heat dissipation fins protrude from a side of the bottom plate, a side of the bottom plate located away from the plurality of heat dissipation fins is thermally coupled to the second heat source, and the two ventilation surfaces of the thermally conductive frame face toward the two openings, respectively.

6. The electronic assembly according to claim 5, further comprising two sealing pads clamped between the two side plates and the first circuit board, respectively.

7. The electronic assembly according to claim 1, wherein the thermally conductive frame is fixed to the base.

8. The electronic assembly according to claim 7, further comprising a screw, wherein the screw comprises a head part and a body part connected to each other, the body part is screwed into the thermally conductive frame and the base, and the head part rests on a side of the base located away from the plurality of heat dissipation fins.

9. The electronic assembly according to claim 7, further comprising two screws, wherein the two screws each comprise a head part and a body part connected to each other, the thermally conductive frame comprises a body part and two mounting protrusions, the two mounting protrusions protrude from two opposite sides of the body part, respectively, the two body parts of the two screws are screwed into the base and are respectively screwed into the two mounting protrusions, and the two head parts of the two screws rest on sides of the two mounting protrusions located away from the base, respectively.

10. The electronic assembly according to claim 1, further comprising a fan, wherein the fan and the first circuit board assembly are located on a side of the heat sink, the fan is fixed to the base of the heat sink, and is configured to blow an airflow flowing to the plurality of heat dissipation fins through the at least one heat dissipation channel.
